(19) United States
(12) Patent Application Publication
(10) Pub. No.: US 2024/0297259 A1
(43) Pub. Date: Sep. 5, 2024

(54) NEGATIVE DIFFERENTIAL RESISTANCE TUNNEL DIODE AND MANUFACTURING METHOD

(71) Applicant: Martin-Luther-Universität Halle-Wittenberg, Halle (Saale) (DE)

(72) Inventors: Ersoy Sasioglu, Salzgitter (DE); Ingrid Mertig, Dresden (DE)

(21) Appl. No.: 18/573,251

(22) PCT Filed: Jun. 1, 2022
(86) PCT No.: PCT/EP2022/064961

§ 371 Date: Dec. 21, 2023

(30) Foreign Application Priority Data
Jun. 24, 2021 (DE) 10 2021 206 526.0

(51) Int. Cl. H01L 29/88; H01L 29/20; H01L 29/24; H01L 29/66

(52) U.S. Cl. CPC H01L 29/88; H01L 29/66969; H01L 29/2003; H01L 29/24

(57) ABSTRACT

The present disclosure concerns a negative differential resistance tunnel diode (100, 200) comprising two terminals (112, 114, 212, 214) for connecting to an electrical circuit as well as a tunnel junction (160, 260) having a first material layer (106, 206) of a cold metal, an insulating material layer of a tunnel barrier (108, 208), and a second material layer (110, 210) of a cold metal. A high peak current IP to valley current IV ratio can thereby be achieved.

The invention concerns a negative differential resistance tunnel diode and manufacturing method.

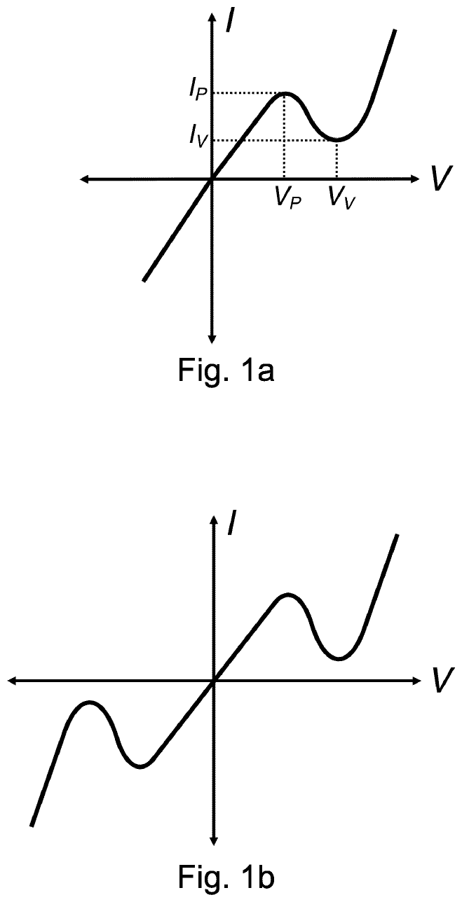

Tunnel diodes represented by an Esaki diode or by a resonant tunnel diode are known as the conventional negative differential resistance (NDR) tunnel diodes. The Esaki diode is a heavily doped (degenerate) p-n-junction diode (see e.g. U.S. Pat. No. 3,033,714A), in which the electron transport in the contact region is via quantum mechanical tunneling under forward bias and it shows negative differential resistance (NDR), i.e., electrical current decreases with increasing bias voltage. FIG. 1a schematically illustrates the current-voltage (I-V) characteristics of an Esaki negative differential resistance tunnel diode. The peak current Iₚ to valley current Iᵥ (see FIG. 1) ratio, in the following abbreviated as PVCR, is a performance measure for such NDR devices. Conventional Esaki NDR tunnel diodes made of Si, Ge or compound semiconductors such as GaAs, GaSb possess small PVCR values of less than 20. The I-V characteristics and PVCR values of the Esaki NDR tunnel diodes are determined mainly by the band structure of the bulk semiconductors. Resonant NDR tunnel diodes can present more than one negative differential resistance regions typically depending on the number of barriers. Present typical applications for negative differential resistance tunnel diodes are circuit applications which need a minimum PVCR of only about 3. There are NDR resonant tunnel diodes based on Si/SiGe or III-V semiconductor materials such as InAlAs/InGaAs that have larger PVCR values of about 70.

As the quantum tunneling is an extremely fast process, conventional devices that are based on tunnel diodes can operate at very high speeds, i.e., in terahertz frequency regime. Memory applications require a PVCR value of e.g. more than 104 (see e.g. Proceedings of the IEEE 87, 571-595 (1999)). But the conventional NDR tunnel diodes cannot provide such a large PVCR value.

In the field of tunnel diodes, a lot of developments have focused on p- or n-doped materials for metal-insulator-metal (MIM) diodes like in U.S. 20150014630A1, EP3734669A1 or WO2019233481A1. Other tunnel diodes are e.g. disclosed in U.S. 20170110564A1 and U.S. 20160155829A1.

The afore-mentioned features known from the state of the art can be combined alone or in arbitrary combination with one of the below described aspects of the present disclosure.

The object is to providing a further developed negative differential resistance tunnel diode.

The problem is solved by the negative differential resistance tunnel diode of claim 1 and the method of the other independent claim. Preferred embodiments are described in the dependent claims.

For solving the problem, a negative differential resistance tunnel diode is provided, which is also called NDR tunnel diode in the following. The NDR tunnel diode comprises two terminals for connecting to an electrical circuit as well as a tunnel junction having a first material layer of a cold metal, an insulating material layer of a tunnel barrier, and a second material layer of a cold metal. The cold metal material of the first and second material layers can be the same cold metal material or different cold metal materials.

The present disclosure provides a new type of NDR tunnel diode.

This new type of cold metal based NDR tunnel diode shows large PVCR values between 10² and 10¹⁰. Memory and logic applications are thereby enabled by this new type of cold metal based NDR tunnel diode. Moreover, this new type of NDR tunnel diodes does not require any semiconducting material and also no doped material in the first and second material layer, which helps to avoids related issues that are described later in further detail.

A diode is generally an electronic component with two electrodes connected to terminals for passing an electrical current flow in only one direction and for blocking a current flow in the opposite direction. A negative differential resistance (NDR) tunnel diode is a diode where electrical current decreases with increasing bias voltage. The peak current Iₚ to valley current Iᵥ ratio (PVCR) is a performance indicator.

In one embodiment, the first material layer and the second material layer are of the same cold metal material. This allows to achieve high PVCR values in a reliable manner at low manufacturing expenses.

In one embodiment, at least one dielectric layer, in particular a dielectric substrate layer, is provided adjacent to the tunnel junction for depositing the first material layer, the insulating material layer of a tunnel barrier, and/or the second material layer. A reliable function with high PVCR values can thereby be achieved. The dielectric layer can be a bottom and/or top capping layer. The dielectric layer electrically insulates the active device region. Preferably, a first dielectric substrate layer allows the deposition of the first material layer and the two terminals. Preferably, a second dielectric capping layer protects the tunnel junction and terminals. In particular, the first and second dielectric layer are at opposites sides of the tunnel junction, preferably perpendicular to a long axis of the first material layer. In one embodiment, the long axes of the first and second dielectric layers are oriented in parallel to each other. Preferably, a long axis of the tunnel barrier or insulation layer is in parallel to the first dielectric layer and/or second dielectric capping layer. In particular, the long axis of the at least one dielectric layer, preferably two dielectric layers, and/or a substrate layer are oriented in parallel to the first dielectric layer and/or second dielectric layer.

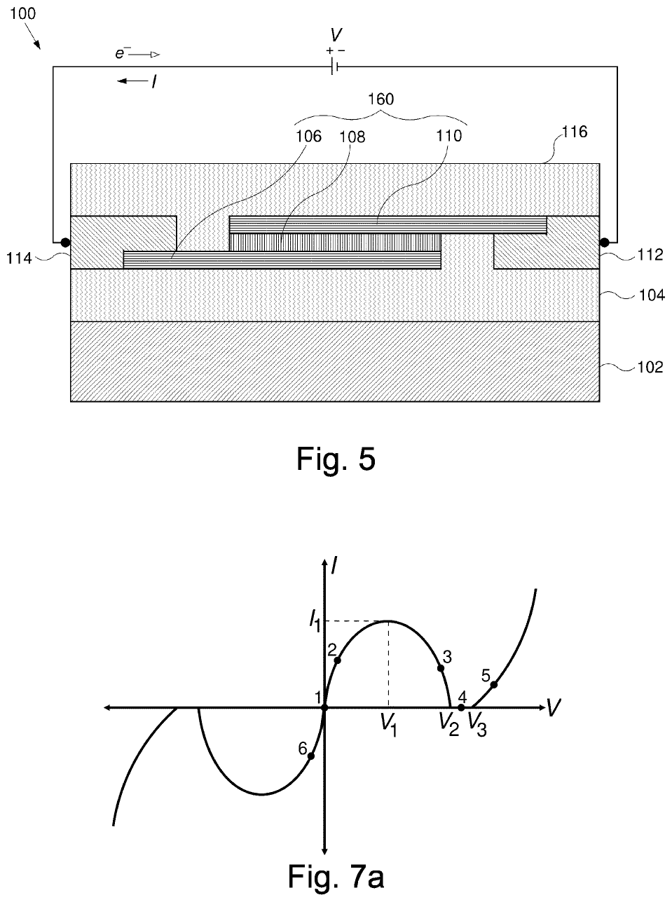

In this document, the term “long axis” is used to describe the direction, in which a layer is extending. In other words, a “long axis” is oriented perpendicular to a short axis, which is oriented in thickness direction of a layer. A long axis of a layer is oriented in parallel to the largest surface of the layer. In particular, a long axis may define a cross section (as shown e.g. in the FIGS. 5 and 6) together with a short axis, which is perpendicular to the long axis, wherein such cross section crosses (shows) both terminals and/or all layers of a tunnel junction or the negative differential resistance tunnel diode.

In one embodiment, the cold metal can be identified by having in a density of states representation (DOS) of electrons of the cold metal (in dependency of energy E): a conduction band width (CBW) starting at a Fermi Energy (E_{F}) level towards higher energy (E), a valence band width (VBW) starting at the Fermi Energy (E_{F}) level towards lower energy (E), a conduction band gap (CBG) adjacent to the conduction band width (CBW) towards higher energy (E), and a valence band gap (VBG) adjacent to the valence band width (VBW) towards lower energy (E). Thus, the width of CBW>0 and VBW>0 applies. Increased PVCR values can thereby be enabled, i.e., increased PVCR values can be achieved with a negative differential resistance tunnel diode by correspondingly selecting a cold metal material for the first and/or second material layer, which has the respective characteristic of CBW, VBW, CBG and/or VBG.

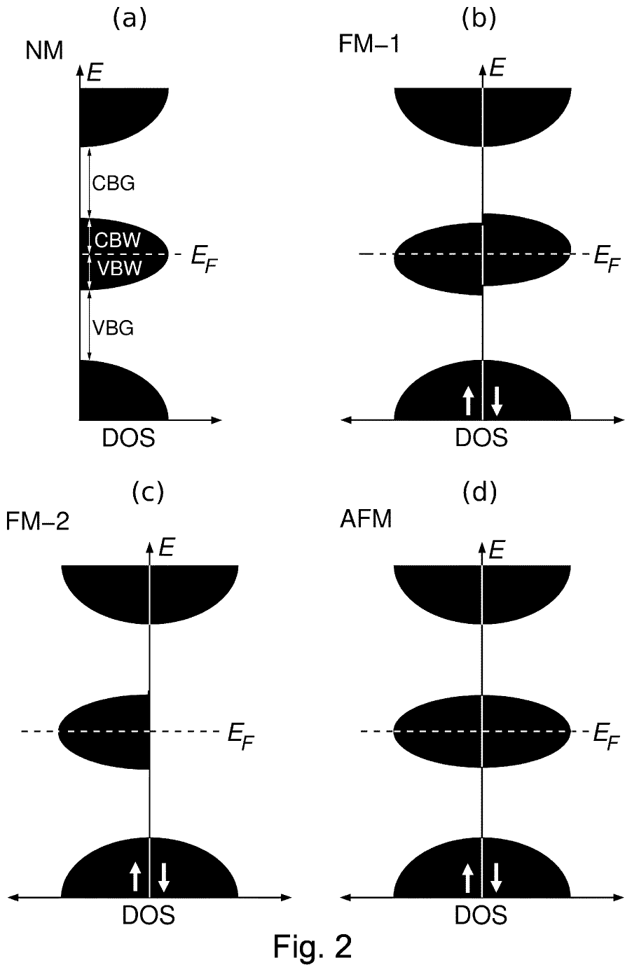

In a diagram with DOS [unit is arbitrary; it can be interpret as a number of different states at a particular energy E that electrons are allowed to occupy, i.e. the number of electron states per unit volume at a particular energy E] on a horizontal axis and the energy E [in eV] on a vertical axis like e.g. shown in FIG. 2, the configuration of CBW, VBW, CBG, and VBG, which was described in this embodiment, is at least on the left side (majority-spin) or on the right side (minority-spin) of a vertical axis. That is to say, this configuration of CBW, VBW, CBG, and VBG can only be on one side of the vertical axis (like in FIG. 2a). It is also possible that CBW and VBW are only on one side of the vertical axis around the Fermi energy level (thus only for one of majority-spin or minority-spin) and at the entire energy range of the CBW, VBW, CBG, and VBG there is no conduction band or valence band on the other side of the vertical axis (like in FIG. 2c). It is also possible that the CBW and VBW, preferably also CBG or VBG are substantially symmetrical to the vertical axis on both sides of the vertical axis (like in FIG. 2d). It is also possible that the conduction band and/or valence band around the Fermi energy level are shifted towards higher or lower energy when comparing both sides of the vertical axis (like in FIG. 2b).

Preferably, VBG>(CBW+VBW). Increased PVCR values can thereby be enabled.

Preferably, CBG>CBW+VBW. Increased PVCR values can thereby be enabled.

Preferably, the CBW extents from 0 eV to an energy that is higher than zero and smaller than 1 eV. Preferably, the VBW extents from 0 eV to an energy that is lower than zero and higher than −1 eV. Increased PVCR values can thereby be enabled.

In particular, the cold metal is not a semiconductor and/or not a doped material. In particular, the cold metal is not used in metal-insulator-metal (MIM) material or MIM diodes.

In one embodiment, a layer thickness of the first material layer and/or a layer thickness of the second material layer amount to most 20 nm, preferably at most 1 nm, particularly preferred about 0.6 nm. Preferably, the first material layer and/or the second material layer amount are provided as a single monolayer or at most 50 atomic layers.

In one embodiment, a layer thickness of the insulating material layer of a tunnel barrier amounts to at most 5 nm, preferably at most 1 nm, particularly preferred about 0.3 nm.

In one embodiment, the cold metal is a material with spin-polarized ground state, in particular a magnetic cold metal, preferably a ferromagnetic cold metal, a half-metallic ferromagnetic cold metal, or an antiferromagnetic cold metal. Alternatively, the cold metal is a paramagnetic cold metal. Increased PVCR values can thereby be enabled.

In one embodiment, the cold metal is TaX₂, wherein X═S, Se or Te. Increased PVCR values can thereby be enabled.

In one embodiment, the tunnel junction is a planar tunnel junction, wherein the first material layer, the insulating material layer of the tunnel barrier and the second material layer are arranged on a same plane and/or each having the thickness of preferably only one monolayer. The tunnel junction can thus be adapted to the available space while still delivering increased PVCR values. In particular the first material layer, the insulating material layer and the second material layer are in this exact order arranged one after another in long axis direction, preferably all three layers extending in the same or substantially the same long axis direction. In one embodiment, the whole planar tunnel junction (or NDR device) consist of one monolayer including a monolayer cold-metal material connected to the insulating tunnel barrier (one monolayer) and second one monolayer cold metal material. In particular, the target thicknesses of all three layers are the same, which in reality—depending on the preciseness of the fabrication process—may lead to derivations of 20% to 100%, especially in the case of a thickness of only one monolayers. A thickness of e.g. five or ten monolayers can be typically fabricated quite precisely. In particular, Regarding the fabrication of layers with an ideally rectangular shape with abutting borders one after another, some overlap in the range of at most 10% or 20% of the area in long axis direction may occur in practice depending on the preciseness of the fabrication process.

In particular, all three layers are deposited over the entire bottom side by the same first dielectric layer. From the top side, the second dielectric capping layer also covers all three layers, but the end of the first material layer, which is not abutting the insulation layer, and the end of the second material layer, which is also not abutting the insulation layer, are covered and fixated by the first or second terminal, respectively.

In one embodiment, the first material layer, the insulating material layer of the tunnel barrier and the second material layer are deposited on a surface of the at least one dielectric substrate layer, which is adjacent to the planar tunnel junction.

In one embodiment, the tunnel junction is a vertical tunnel junction. The first material layer, the insulating material layer of the tunnel barrier and the second material layer are in this case arranged in a stacked manner. All three layers are then arranged one over another in direction of the short axis, i.e. the thickness direction. All three layers, preferably also the dielectric bottom and/or capping layer, are arranged in parallel to each other. The long axes of parallel layers are in parallel to each other.

In one embodiment, the first material layer, the insulating material layer of the tunnel barrier and/or the second material layer are twisted with an offset angle relatively to each other. Increased conductivity can thereby be obtained. Twisted layers are arranged with an offset angled relatively to each other. The offset angle measures a rotation of a layer in the plane of the layer, i.e. about an axis that is oriented orthogonal to the layers. The layers are arranged in parallel to each other. A parallel arrangement or an arrangement under an offset angle is based on the atomic structure of the layers, which forms a repeating pattern of arranged atoms. When for example a layer is formed of several parallel and/or linear rows of atoms, the orientation of such row can be taken as zero angle. When another layer is arranged in parallel to said layer, which defines the zero angle, and the orientation of its rows of atoms is aligned with the zero angle, the offset angle is zero. And in the case the other layer is rotated such that its rows of atoms form an angle relatively to the atomic rows of said layer, which defines the zero angle, this formed angle is the offset angle.

In one embodiment, the first and second material layers are twisted and/or the first material layer is arranged with an offset angle relatively to the second material layer. Increased conductivity can thereby be obtained. Preferably, where the first material layer and the second material layer are arranged one over another in the tunnel junction (vertical tunnel junction), the first and second material layers are twisted (relatively to each other). The layers are twisted by being arranged in a position, where the first material layer has a different rotational orientation compared to the second layer. That is to say, the first and second material layers have a rotational offset. Such rotation is about an axis that is extending orthogonal to the first and second material layers. Preferably, the offset angle is at least 0.5° and/or at most 10°, especially preferred about 1.1°. Increased conductivity can be achieved. In another embodiment, the offset angle can range between 11° and 365°. In one embodiment, the first material layer and the tunnel barrier are twisted and/or the first material layer is arranged with an offset angle relatively to the tunnel barrier. In one embodiment, the second material layer and the tunnel barrier are twisted and/or the second material layer is arranged with an offset angle relatively to the tunnel barrier. In one embodiment, twisting of the tunnel barrier layer with respect to the first and second material layers is implemented, and/or all three layers (tunnel barrier, first and second material layers) are twisted with respect to each other.

In one embodiment, in particular having a vertical tunnel junction, the first material layer is protruding the insulating material layer of the tunnel barrier in a horizontal direction, i.e. in long axis direction, for connecting to the first terminal. Alternatively or additionally, the second material layer is protruding the insulating material layer of the tunnel barrier in an opposite horizontal direction for connecting to the second terminal.

In one embodiment, the at least one dielectric layer fills a horizontal space between one of the terminals and the tunnel barrier. For example, when the first material layer is at the bottom of the tunnel junction and protrudes the insulating layer to the left side, the protruding end reaches the first terminal. The thickness of the terminal is preferably twice or three times of the thickness of the first material layer. In particular, a vertical (right) border of the terminal extends vertically, preferably starting from the top surface of the first material layer, specifically the protruding portion thereof. The first terminal is preferably applied onto the end portion of the protruding end of the first material layer and to the first dielectric layer ahead of said end of the first material layer. In particular, the vertical border of the terminal forms a L-shape with the protruding portion of the first material layer, which is not covered by the terminal and not covered by the insulation layer. Preferably, said L-shape forms a U-shape together with the opposed ends of the insulating layer and the second material layer. In one embodiment, a U-shaped space is formed between the terminal and the junction. In particular, this space is filed by a dielectric layer, which thus has a T-shape.

In one embodiment, the tunnel junction is arranged between both terminals in a direction of long axes of the first and second material layer, which are extending in parallel to each other.

Another aspect of the disclosure concerns a method for manufacturing a negative differential resistance tunnel diode, comprising the steps of:
Depositing a first material layer of a cold metal, in particular on top of a dielectric substrate, an insulating material layer of a tunnel barrier and a second material layer of a cold metal; and
Depositing a first terminal to the first material layer and the second terminal to the second material layer.

In one embodiment, a further step includes depositing a dielectric layer, preferably a capping layer, on top of tunnel junction and terminal electrodes.

A negative differential resistance tunnel diode with the advantages described above in the context of the respective aspect of the disclosure, whose definitions and embodiments also apply to this aspect of the disclosure, can thereby be achieved.

Another aspect of the disclosure concerns a use of the negative differential resistance tunnel diode of one of the preceding aspects of the disclosure to obtain negative differential resistance, or for memory and/or logic applications. Also for this aspect of the disclosure, the above definitions and embodiments apply.

Further embodiments are described below based on the following figures:

FIG. 1a is a schematic representation of the current-voltage (I-V) characteristics of conventional negative differential resistance diodes like Esaki diodes;

FIG. 1b is a schematic representation of the current-voltage (I-V) characteristics of conventional negative differential resistance resonant-tunneling diodes.

FIG. 2(a) is a schematic representation of the density of states (DOS) of the electrons in a paramagnetic cold metal;

FIG. 2(b) is a schematic representation of the spin-resolved density of states (DOS) of the electrons in a ferromagnetic cold metal;

FIG. 2(c) is a schematic representation of the spin-resolved density of states (DOS) of the electrons in a ferromagnetic half-metallic cold metal;

FIG. 2(d) is a schematic representation of the spin-resolved density of states (DOS) of the electrons in an antiferro-magnetic cold metal;

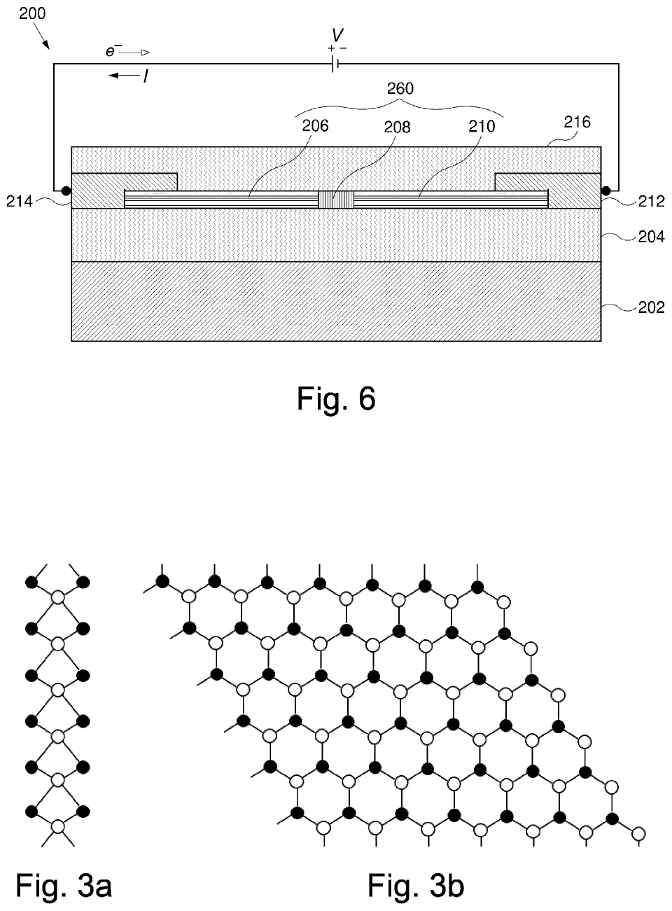

FIG. 3a is a schematic side view of an atomic structure of a monolayer of e.g. TaSe₂ or NbSe₂ of a NDR tunnel diode according to the present disclosure;

FIG. 3b is a schematic top view of the monolayer of FIG. 3a;

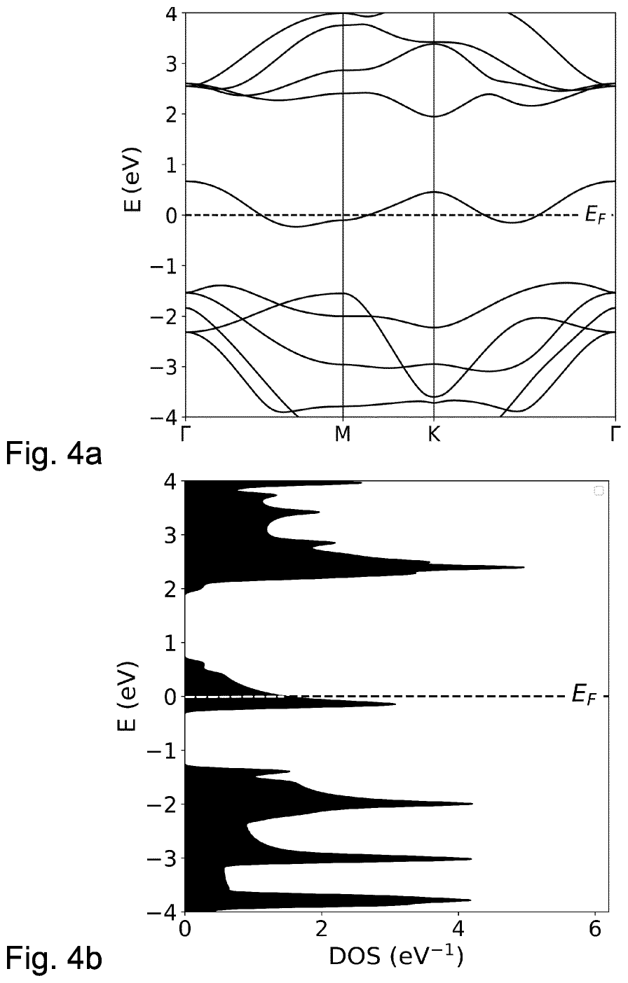

FIG. 4a is chart showing an electronic band structure of a monolayer cold metal of a NDR tunnel diode according to the present disclosure; and

FIG. 4b is a chart showing density of states of the monolayer cold metal of the NDR tunnel diode of FIG. 4a;

FIG. 5 is a schematic cross section view of the layers of a vertical NDR tunnel diode according to the present disclosure having electrical terminals;

FIG. 6 is a schematic cross section view of the layers of a planar NDR tunnel diode according to the present disclosure having electrical terminals;

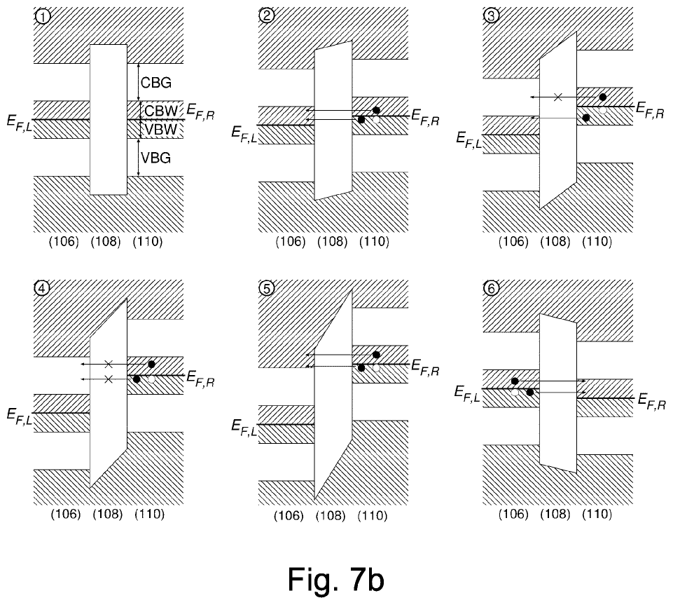

FIG. 7a is schematic representation of the current-voltage (I-V) characteristics of the NDR tunnel diode e.g. of FIG. 5;

FIG. 7b is a schematic representation of the energy-band diagram of the NDR tunnel diode for various applied bias voltages;

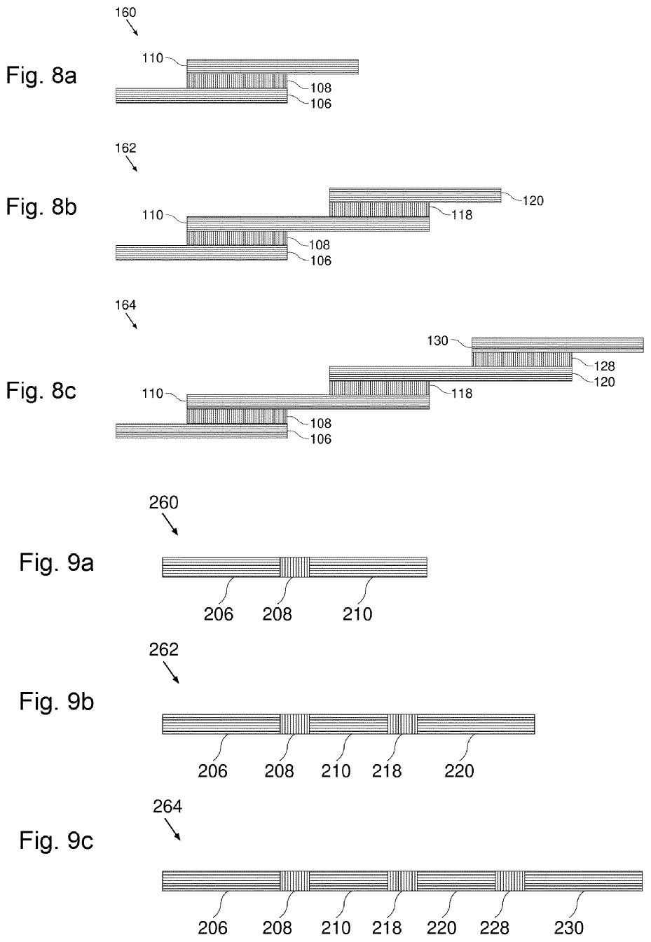

FIGS. 8a to 8c: Schematic cross section views of the layers of a multiple barrier vertical NDR tunnel diode according to the present disclosure with single (FIG. 8a), double (FIG. 8b) or triple (FIG. 8c) barrier tunnel junctions;

FIGS. 9a to 9c: Schematic cross section view of the layers of a multiple barrier planar NDR tunnel diode according to the present disclosure with single (FIG. 9a), double (FIG. 9b) or triple (FIG. 9c) barrier tunnel junctions.

FIG. 1a schematically shows a I-V characteristics of the Esaki tunnel diode, in which as the voltage increases across the junction, tunneling current through the junction increases to a peak value Iₚ and then decreases to a characteristic valley value Iᵥ, i.e., I-V characteristics of the tunnel diode takes the N-shape form. In solid-state electronics, NDR effect is a property of some tunnel diodes in which an increase in voltage across the diode's electrodes results in a decrease in electric current through it. The discovery of quantum mechanical tunneling by Esaki (see document U.S. Pat. No. 3,033,714A) in heavily doped Ge p-n junctions created the first solid-state device with NDR characteristics. In one embodiment, also the tunnel diode of the present disclosure may take an N-shape form. The first section of the I-V curve, where the tunneling occurs has positive slope, while the negative slope region is where tunneling ceases. Thus, generally spoken, it is the absence of tunneling that gives rise to the NDR effect.

The PVCR values for known Esaki tunnel diodes are usually small, between 2 and 20, which makes them unsuitable for memory applications. The I-V characteristics of the Esaki tunnel diodes are determined e.g. by the band structure of the bulk semiconductors and there exists generally three different mechanisms contributing into the current density under the forward bias: i) interband tunneling, ii) excess current through defect-assisted tunneling, and iii) diffusion current. The second mechanism, i.e., the defect-assisted tunneling may cause issues (see e.g. IEEE Transactions on Electron Devices, 57, 11, (2010)) Another issue in semiconductor-based tunnel diodes is the control of doping at the junction interface. A none-abrupt doping transitions between n-type region and p-type region may reduce the performance in these devices. However, as the device dimensions get smaller and smaller the precise control of doping at the atomic scale becomes difficult or even impossible. Esaki diodes based on semiconducting transition-metal dichalcogenides exhibit PVCR of about 1.8 at room temperature [see Nano Lett. 15, 5791 (2015)].

FIG. 1b schematically shows a I-V characteristics of a conventional resonant tunneling diodes (RTDs) that can exhibit NDR effect. RTDs are typically realized in III-V (such as InAlAs/InGaAs) and II-VI compound semiconductor systems, where heterojunctions made up of various III-V (II-VI) compound semiconductors are used to create the double, triples, or multiple potential barriers in the conduction band or valence band. Depending on the number of barriers the RTDs can exhibit multiples NDR regions. A drawback of III-V RTDs is the use of III-V compound semiconductors whose processing is incompatible with the current silicon processing technology and the cost is rather high. In RTDs the measured PVCR values are limited by a value of about 70 at room temperature.

In one embodiment of the negative differential resistance tunnel diode of the present disclosure, the NDR effect allows memory and logic circuit applications. As the quantum tunneling is extremely fast process, a device based on such negative differential resistance tunnel diode of the present disclosure can operate at very high frequencies, i.e., in Terahertz regime. In some embodiments, which are described later in more detail, multiple NDR regions are present in I-V characteristics of RTDs, which allows to provide stable states that reduce device count and circuit complexity with increased functionality per device and lower the power consumption for switching in logic and memory applications.

For typical circuit applications such as oscillators, amplifiers, etc., a minimum PVCR of about 3 is needed, however for memory and logic applications, for instance, a far higher PVCR value is required, which conventional NDR diodes can not provide so that they can at present not be used for memory and logic applications.

The negative differential resistance tunnel diode of the present disclosure overcomes the low PVCR value issue of the conventional tunnel diodes and can reach PVCR values of at least 10² and/or at most 10⁶ or even at most 10¹⁰, in particular at room temperature. In one embodiment, a use of the negative differential resistance tunnel diode of the present disclosure is a logic application, preferably a fast switch, a high frequency oscillator, or a neuromorphic computing device. In particular, a use of the negative differential resistance tunnel diode of the present disclosure is a memory application, preferably SRAM.

In particular, the provided tunnel diode does not require any semiconductor element and/or doping. In particular, it has a simple structure with two cold metal material layers (electrodes), which each are connected to a terminal, and/or a thin tunnel barrier. In particular, an operating frequency in THz regime can be achieved. In particular, use for ultrahigh speed electronics is enabled. The I-V characteristics and PVCR values of the new type of cold-metal tunnel diode of the present disclosure can be determined by a band width around the Fermi level and energy gaps above and below the Fermi level of the constituting cold metals.

In summary, the new type of NDR tunnel diode of the present disclosure enables a very high PVCR value suitable for logic and/or memory applications, such as SRAM. Another advantage is that the new type of NDR tunnel diode of the present disclosure can be provided semiconductor-free, thus manufacturing effort and costs are reduced, especially at nanoscale. Another advantage is that in contrast to conventional NDR devices based on semiconductors with p- and n-type uniform doping, which becomes more and more difficult as the device dimensions get smaller and smaller, new type of NDR tunnel diode of the present disclosure is scalable to very small sizes, in particular to nanoscale range. Another advantage is that in conventional NDR devices the negative resistance region is limited to very low voltages, usually between 0.1 V and 0.6 V and thus they are not suitable for high power applications, while in the new type of NDR tunnel diode of the present disclosure this region can be tuned via material selection. Cold metals are the key components of the provided new type of NDR tunnel diode of the present disclosure. In one embodiment, the cold metal is a two-dimensional material or is provided in the diode of the present disclosure as a two-dimensional material. In particular, two-dimensional materials are confined in one direction and have sheet like morphology, which can be identified e.g. by microscopic techniques. Two-dimensional materials extend in two dimensions (plane of a sheet) to an extend outside the nanoscale and/or in one dimension (thickness direction) only a single or few atomic layers.

It is denoted herein width of the band below Fermi level E_{F} by “VBW”, above Fermi level E_{F} by “CBW”, gaps in valence band by “VBG”, and gaps in conduction band by “CBG”. Here VBW and VBG stand for valence band width and valence band gap, respectively.

FIG. 2 presents schematic density of states (DOS) picture of different kinds of cold metal. FIG. 2(a) presents schematic DOS picture of a paramagnetic cold metal. In particular, the cold metal is paramagnetic cold metal, i.e. non-spin-polarized. As can be seen, a cold metal possesses states (narrow band) around the Fermi level E_{F} and gaps in the valence and conduction band (see also FIG. 4). In particular, the cold metal is a two-dimensional material.

In one alternative or additional embodiment, the cold metal is 1H TaX₂, 2H TaX₂, 1H NbX₂, or 2H NbX₂ (X═S, Se, or Te). “H” indicate hexagonal symmetry. Alternatively or additionally, the cold metal is a transition-metal dichalcogenides cold metal.

FIGS. 2(b), (c) and (d) show DOS representations where the majority-spin bands are shown on the left-hand side of the vertical axis and the minority-spin bands on the right-hand side. In one embodiment (see e.g. FIGS. 2(b), (c) and/or (d)), the cold metal is a material with spin polarized ground state, which show cold metallic behavior. FIG. 2(b) shows the DOS of a ferromagnetic cold metal with a small exchange splitting. CBW and VBW are shifted by up to 30% towards higher or lower Energy when comparing both sides of the vertical axis, thus for minority and majority spin. FIG. 2(c) shows the DOS of a half-metallic cold metal, in particular presented by a two-dimensional material. CBW and VBW is only present for one of majority and minority spin, in particular only for majority spin. In one embodiment, the half-metallic cold metal is one of AgF₂, CoCl₂, DySBr, DySI, FeBr₂, FeI₂, NdOBr, SmOBr, and V₂I₆. FIG. 2(d) depicts the schematic DOS of an antiferromagnetic cold metal. The valence and conduction band (CBW, VBW) are similar or same for both, majority and minority spin. In particular, the antiferromagnetic cold metal is a two-dimensional material such as Fe₂I₆, V₂ClO₂, V₂BrO₂, and Cr₂P₂S₆.

Photoemission and inverse-photoemission spectroscopy can be used to measure the features of a cold metal of one of the above described embodiments. An electronic structure of a material and thus the presents of a cold metal can thereby be identified. Alternatively or additionally, spin-resolved photoemission spectroscopy can be used to directly identifying electronic structure of magnetic materials. Alternatively or additionally, spin-polarized scanning tunneling microscopy can be used to indirectly identifying electronic structure of magnetic materials, which provide however only limited information on the electronic structure of magnetic materials.

FIG. 3 shows an atomic structure of a layered cold metal like NbSe₂ or TaSe₂, in which a plane of Nb or Ta atoms is sandwiched by planes of selenium ions. These three strata form a monolayer of NbSe₂. Bulk NbSe₂ is formed of stacked monolayers, which are held together by weak van der Waals interactions. Crystalline NbSe₂ is found in nature in several forms, including 1H, 2H, and 4H. “H” indicate hexagonal symmetry.

FIG. 4a shows an electronic band structure of the NbSe₂ compound, in particular the compound of FIG. 3, along the high symmetry lines in Brillouin zone. In particular, the cold metal has a H-structure. FIG. 4a shows a cold metal with a H-structure. The dashed line denotes the Fermi level E_{F}, which is set to zero energy. As seen from FIG. 4a a single band, which crosses the Fermi level, is disentangled from the rest of the bands giving rise to cold metallic behavior. The valence band gap (VBG) is in particular around 1 eV, while the conduction band gap (CBG) is slightly larger, preferably at least 10% or 20% larger, which can also be seen from FIG. 4b.

FIG. 4b illustrates the presence of a cold metal by means of the DOS representation in analogy to FIG. 2 by revealing a conduction band width (CBW) starting at a Fermi Energy (E_{F}) level towards higher energy (E), a valence band width (VBW) starting at the Fermi Energy (E_{F}) level towards lower energy (E), a conduction band gap (CBG) adjacent to the conduction band width (CBW) towards higher energy (E), and a valence band gap (VBG) adjacent to the valence band width (VBW) towards lower energy (E).

In Particular, FIG. 4b shows a density of states (DOS) of the NbSe₂ compound of FIG. 4a. The relative sizes of the VBG, CBG as well as the valence and conduction band width can be used to determining I-V characteristics of the NDR tunnel diode. The band structure and density of states shown in FIGS. 4a and 4b can be calculated using the density functional theory within the generalized gradient approximation (GGA-½) for the exchange-correlation functional with a dense k-point mesh of 40×40×1.

FIG. 5 shows a vertical NDR tunnel diode 100 according to the present disclosure. It preferably has a structure in form of a material layer stack with layers that are arranged over one another and/or firmly connected with each other. The tunnel diode 100 preferably comprises a support layer or substrate 102 such as a silicon wafer, a dielectric layer 104, thereon arranged electrodes in form of cold metal material layers 106, 110 and the tunnel barrier 108. The cold metal layers 106 and 110 are each connected to terminals 114 and 112 for electrical connecting the vertical NDR tunnel diode junction 160 to an external electrical circuit, in particular with the voltage V. Preferably, another dielectric capping layer 116 is formed on top of vertical tunnel junction 160 and/or terminals 112 and 114. The vertical tunnel barrier junction 160 comprises or consists of three layers, namely a cold metal material layer 106, an insulating tunnel barrier 108, and another cold metal material layer 112. In tunnel barrier junction 160 the electrical transport takes place in the vertical direction. In addition to vertical NDR tunnel diode shown in FIG. 5, a planar diode can be also realized by using cold metals.

FIG. 6 shows a planar NDR tunnel diode 200 according to present disclosure. The NDR tunnel diode includes a support layer or substrate 202 such as a silicon wafer, a dielectric layer 204, a thereon arranged electrodes in form of cold metal material layers 206, 210 and a tunnel barrier 208. The cold metal layers 206 and 210 are each connected to terminals 214 and 212 for electrical connecting the planar NDR tunnel diode junction 260 to an external electrical circuit, preferably with the voltage V. Another dielectric capping layer 216 is formed on top of planar tunnel junction 260 and terminals 212 and 214. The planar tunnel barrier junction 260 comprises or consists of three layers, a cold metal material layer 206, a insulating tunnel barrier 208, and another cold metal material layer 210. In tunnel barrier junction 260 the electrical transport takes place within the plane.

The tunnel barrier 108, 208 is preferably made of an insulator. In particular, the tunnel barrier 108, 208 has a band gap of at least 1 eV. The tunnel barrier 108, 208 is for example made of hexagonal BN, MgO, MoS₂, MoSe₂, MoTe₂, WS₂, WSe₂, WTe₂, HfS₂ PtS₂, PtSe₂, GaS, or GaSe. Not preferred, but generally possible is a large band gap semiconductor for use as tunnel barrier. The cold metals 106, 206, 110, 210 are preferably two-dimensional paramagnetic Van der Waals materials and/or NbX₂, TaX₂ (X═S, Se, Te), NbSSe, NbSTe, NbSeTe, TaSSe, TaSTe, TaSeTe. The cold metals 106, 206, 110, 210 may be non-stoichiometric two-dimensional Van der Waals materials, which can be expressed by the formula X₁₋ₘX′ₘZ₂₋₂ₙZ′₂ₙ, where 0≤m≤1 and where 0≤n≤1. The X and X′ are different transition metal elements such as Ti, V, Cr, Zr, Nb, Mo, Hf, Ta, or W. The Z and Z′ are different chalcogen elements such as O, S, Se, or Te. The cold metals 106, 206, 110, 210 may be two-dimensional magnetic materials and/or AgF₂, CoCl₂, DySBr, DySI, FeBr₂, FeI₂, NdOBr, SmOBr, V₂I₆, Fe₂I₆, V₂ClO₂, V₂BrO₂, and Cr₂P₂S₆. The dielectric layer 104, 204 and dielectric capping layer 116, 216 may be SiO₂, HfO₂, hexagonal BN, or ZrO₂. The terminals 114, 214, 112, 212 may be composed of different materials, such as graphene, Sc, Ti, Ni, Ru, Rh, Cu, Pt, Au, Ag, Pd, Al, Ta, or CuN.

A first example of the negative differential resistance tunnel diode 100, 200 of the present disclosure, in particular the stacked cold-metal NDR tunnel diode 100 of FIG. 5, has the following structure (preferable thickness range in squared bracket): Si as substrate 102—SiO₂ [thickness of 200-300 nm] as dielectric layer 104—Au as terminal 112 [5-30 nm]—TaSe₂ or NbS₂ as cold metal material layer 104 [0.6-20 nm]—h-BN as tunnel barrier 108 [0.3-5 nm]—TaSe₂ or NbS₂ as the other cold metal material layer 110 [0.6-20 nm]—Au [5-30 nm] as terminal 114—HfO₂ [2-10 nm] as dielectric capping layer 116.

A second example of the negative differential resistance tunnel diode 100, 200 of the present disclosure, in particular the stacked cold-metal NDR tunnel diode 100 of FIG. 5, has the following structure (preferable thickness range in squared bracket): Si as substrate 102—SiO₂ [thickness of 200-300 nm] as dielectric layer 104-Pt as terminal 112 [5-30 nm]—TaS₂ as cold metal material layer 104 [0.6-20 nm]-h-BN as tunnel barrier 108 [0.3-5 nm]—NbS₂ as the other cold metal material layer 110 [0.6-20 nm]-Pt [5-30 nm] as terminal 114—HfO₂ [2-10 nm] as dielectric capping layer 116.

A third example of the negative differential resistance tunnel diode 100, 200 of the present disclosure, in particular the cold-metal NDR tunnel diode 200 of FIG. 6, has the following structure (preferable thickness range in squared bracket): Si as substrate 202—SiO₂ [thickness of 200-300 nm] as the dielectric layer 204-Au as terminal 212 [5-30 nm]—TaSe₂ or NbSe₂ as cold metal material layer 204 [0.6 nm]—HfS₂ as tunnel barrier 208 [0.6 nm]—TaSe₂ or NbSe₂ as cold metal material layer 210 [0.6 nm and/or one monolayer]—Au [5-30 nm] as terminal 214. —HfO₂ [2-10 nm] as top dielectric capping layer 216. The tunnel barrier HfS₂ can be provided with a thickness of 0.6 nm in vertical direction and/or 1-4 nm along the horizontal (long axis) direction.

The device, in particular the device of the first example or of FIG. 5, can be fabricated preferably with the scotch tape method. In a preferred first step of the manufacturing method, flakes of the cold metal material, in particular TaSe₂, NbS₂ and/or hexagonal-BN (h-BN), can be mechanically exfoliated from a bulk crystal. A preferable next step includes to locate the flakes onto a substrate, preferably 300 nm thick SiO₂ covered silicon substrate. Because the scotch tape method is not a well scalable and well-controlled method, the thickness of the flake or cold metal layer can vary from one monolayer to several atomic layers. In a preferable next step, terminals, e.g. of Au [20 nm] can be sequentially deposited by DC magnetron sputtering system and/or be patterned at room temperature, preferably by using e-beam lithography and/or lift-off processes. Besides the scotch tape technique, chemical vapour deposition (CVD) method can employed to synthesize ultra-thin (one monolayer) cold metal flakes or layers, in particular of TaSe₂, NbS₂ and h-BN. In contrast to scotch tape method, the CVD is a well-controlled method for layer by layer fabrication of the devices based on semiconducting transition metal dichalcogenides (TMDs) such as MoS₂ or WSe₂ on various substrates. The molecular beam epitaxy (MBE) can be also used to grow e.g. TaSe₂, NbS₂ or h-BN under ultrahigh vacuum. However, MBE requires specific substrates like h-BN and graphene.

In the NDR tunnel diode 100 shown FIG. 5 and/or FIG. 6, the cold metal material layers can be the same material or different materials. An example for the embodiment with same materials includes TaSe₂ or NbS₂. In the NDR tunnel diode 100 shown FIG. 5 and/or FIG. 6, the cold metal material layers can be a magnetic material. In the NDR tunnel diode 100 shown FIG. 5, the thickness of the cold metal layers 106 and 110 can vary from one monolayer (0.6 nm) to several layers (20 nm). In the NDR tunnel diode 100 shown FIG. 5, the thickness of the tunnel barrier layer 108 can vary from one monolayer (0.3 nm) to several layers (5 nm). As the thickness of the tunnel barrier increases the tunnel current decreases exponentially. In the NDR tunnel diode 200 shown FIG. 6, the thickness of the cold metal layers 206 and 210 and tunnel barrier layer 208 can vary from one monolayer (0.6 nm) to several layers (20 nm) in vertical direction. The thickness of the tunnel barrier 208 might vary between 1 nm to 5 nm in horizontal direction.

FIG. 7a is schematic representation of the current-voltage (I-V) characteristics of the negative differential resistance tunnel diode of the present disclosure for various applied bias voltages, in particular of the diode with the structure shown in FIG. 5. FIG. 7a will be described in detailed in the context of FIG. 7b in the following.

FIG. 7b shows energy band diagrams of the negative differential resistance tunnel diode of the present disclosure, in particular of the diode with the structure shown in FIG. 5. The energy band diagram of the insulating tunnel barrier is represented by rectangular when no bias voltage is applied to a terminal, and by a trapezoid when a finite bias is applied to one of the terminals. In panel-1 (diagram with index “1” in a cycle) of the FIG. 7b, the VBW and VBG stand for valence band width and valence band gap, as well as CBW and CBG stand for conduction band width and conduction band gap. E_{F,L} and E_{F,R} denote the Fermi levels for the left and right cold metal material layer (electrodes). For a simple tunnel barrier, the tunneling current I(V) for a bias voltage V is given by the expression

$$I ( V ) ∼ {\sum }_{σ} {\int }_{- ∞}^{+ ∞} {ρ}_{CM , L} ( E + eV ) {ρ}_{CM , R} ( E ) {\vert T ( V ) \vert}^{2} f ( E ) [ 1 - f ( E + eV ) ] dE ,$$

where ρ_{CM,L}(E+eV) and β_{CM,R}(E) denote the DOS of the left and right cold metal material layer (electrode) and f(E) being the Fermi distribution function. T(V) is the transmission probability and being proportional to e^{-d\sqrt{ϕ-V}}, where d is the thickness of tunnel barrier and φ being the barrier height. It is noted that in the NDR tunnel diode, the current direction is opposite to the electron motion.

As shown in panel-2 of FIG. 7b, when a positive bias voltage is applied to the left cold metal material layer (electrode), electrons from the occupied valence band of the right cold metal material layer (electrode) tunnel through the insulating barrier into the unoccupied conduction band of the left cold metal material layer (electrode). With increasing bias voltage V, the current I increases up to a peak value I₁ then it starts to decrease and finally for a specific value of bias voltage V₂ the current becomes zero. This is because the conduction band of the left cold metal material layer (electrode) has an energy gap (CBG) and thus within the applied potential window there is no available states for the electrons to tunnel into resulting in a zero current (see panel-4 in FIG. 7b). At zero temperature this current is exactly zero, while at finite temperature very few thermally excited high energy electrons that are at the tail of the Fermi-Dirac distribution of the right cold metal material layer (electrode) can tunnel into the left cold metal material layer (electrode) giving rise to an extremely small current and thus the PVCR takes finite value instead of infinite value at zero temperature. The current stays zero between the bias potential V₂ and V₃ and after V₃ the current starts to increase again. The region between the bias potential V₁ and V₂ is the NDR region. The I-V characteristics of a cold metal tunnel diode shown in FIG. 7a having the same left and right cold metal material layers (electrodes) can be determined by one or more of the following four parameters. These are the band width and gap of the valence and conduction band electrons (VBW, CBW, VBG, and CBG). Especially high PVCR values can be obtained when one or more of the following three conditions apply:
In particular, a first condition is: VBW>0, CBW>0 and in particular VBG>0, CBG>0
In particular, a second condition is: VBG>CBW+VBW
In particular, a third condition is: CBG>CBW+VBW

The bias voltages V₁, V₂, and V₃ in FIG. 7a are approximately given by
in particular: V₁=max{VBW/2, CBW/2}
in particular: V₂=VBW+CBW
in particular: V₃=min{VBG, CBG}

The first condition leads—independently form the second and/or third condition—to increased PVCR values. The PCVR value can be increased significantly further when the second and/or third condition is satisfied in combination with the first condition. In the above, it was focused on the forward bias and NDR effect. Of course, in the same way, for a reverse bias one can observe the same NDR effect, i.e., the I-V characteristics of the cold metal tunnel diode turns out to be anti-symmetric if the left and right cold metal material layers (electrodes) are the same. A cold metal material selection following the above described conditions based on VBW, CBW, VBG, and CBG allows to achieve desired I-V characteristics for increased diode performance especially with regards to the PCVR value. For instance, the NRD region (V₁-V₂ interval) can be tuned by tuning the VBW, CBW, VBG, and CBG parameters. In particular, two-dimensional van der Waals materials offer the possibility of tuning these electronic structure parameters by simple means, i.e., by increasing the number of layers in the cold metal material layers (electrodes) of the tunnel diode. For instance monolayer NbSe₂ or TaSe₂ satisfies all three conditions above (see FIG. 4) as an electrode material for one or both cold metal material layers 106, 206, 110, 210. In one embodiment, in particular using NbSe₂ as cold metal, the following ranges apply:
in particular, VBW is at least 0.2 eV and/or at most 0.4 eV, preferably about 0.24 eV;
in particular, CBW is at least 0.55 eV and/or at most 0.75 eV, preferably about 0.65 eV;
in particular, VBG is at least 1.00 eV and/or at most 1.18 eV, preferably about 1.08 eV;
in particular, CBG is at least 1.19 eV and/or at most 1.39 eV, preferably about 1.29 eV.

In one embodiment, the cold metal negative differential resistance tunnel diode allows NDR effect for both forward bias and reverse bias voltages.

In one embodiment, the cold metal negative differential resistance tunnel diode posses anti-symmetric I-V curves when the left and right cold metal material layers (electrodes) are made of the same materials.

In one embodiment, the cold metal negative differential resistance tunnel diode allows to be tuned to a desired voltage window for a specific application by means of cold metal material selection based on one or more of the first, second or third condition described above that depends on VBW, CBW, VBG, and/or CBG that allow to obtain the desired I-V characteristics. For instance, tunnel diodes having a NDR region at small bias voltages can be used for low-power memory and/or logic applications. And for instance, tunnel diodes having a NDR region at large bias voltages can be used for high-power memory and/or logic applications.

In one embodiment, the cold metal negative differential resistance tunnel diode has a much higher current drive capability and low resistance compared to conventional NDR diodes.

Preferably, multiple NDR regions are present in I-V characteristics of resonant tunneling diodes, which allows to provide stable states that reduce device count and circuit complexity with increased functionality per device and lower the power consumption for switching in logic and memory applications.

In one embodiment, the cold metal negative differential resistance tunnel diode of the present disclosure has double barrier tunnel junctions or triple barrier tunnel junctions. Double barrier or triple barrier tunnel junctions enable further applications, like in spintronics. Specifically, it becomes possible to easily tune the peak and valley current densities and to easily tune the peak and valley voltages. Creating multiple NDR regions also facilitates neuromorphic computing.

FIG. 8a shows a multiple barrier vertical NDR tunnel diode with single barrier tunnel junction. In this embodiment, the tunnel junction 160 has a first material layer 106 of a cold metal, an insulating material layer of a tunnel barrier 108, and a second material layer 110 of a cold metal. These layers are arranged or stacked over each other.

FIG. 8b shows a multiple barrier vertical NDR tunnel diode with double barrier tunnel junctions. In this embodiment, the tunnel junction 162 has a first material layer 106 of a cold metal, an insulating material layer of a tunnel barrier 108, a second material layer 110 of a cold metal, another insulating material layer of a tunnel barrier 118, and another material layer 120 of a cold metal. These layers are arranged or stacked in this exact order over each other. In one embodiment, all cold metal layers are made of the same material and/or all tunnel barriers are made of the same material. In one embodiment, all cold metal layers are made of different cold metal materials and/or all tunnel barriers are made of different materials. In particular, different materials are used for the cold metal material layers and tunnel barrier layers.

FIG. 8c shows a multiple barrier vertical NDR tunnel diode with triple barrier tunnel junctions. In this embodiment, the tunnel junction 164 has a first material layer 106 of a cold metal, an insulating material layer of a tunnel barrier 108, a second material layer 110 of a cold metal, another insulating material layer of a tunnel barrier 118, another material layer 120 of a cold metal, a further insulating material layer of a tunnel barrier 128, and a further material layer 130 of a cold metal. These layers are arranged or stacked in this exact order over each other. All cold metal layers can be made of the same material and/or all tunnel barriers can be made of the same material. In one embodiment, all cold metal layers are made of different cold metal materials and/or all tunnel barriers are made of different materials. In particular, different materials are used for the cold metal material layers and tunnel barrier layers.

FIG. 9a shows a multiple barrier planar NDR tunnel diode with single barrier tunnel junction. In this embodiment, the tunnel junction 260 has a first material layer 206 of a cold metal, an insulating material layer of a tunnel barrier 208, and a second material layer 210 of a cold metal. These layers are arranged in this exact order one after another aligned in one plane.

FIG. 9b shows a multiple barrier planar NDR tunnel diode with double barrier tunnel junctions. In this embodiment, the tunnel junction 262 has a first material layer 206 of a cold metal, an insulating material layer of a tunnel barrier 208, a second material layer 210 of a cold metal, another insulating material layer of a tunnel barrier 218, and another material layer 220 of a cold metal. These layers are arranged in this exact order one after another aligned in one plane. All cold metal layers can be made of the same material and/or all tunnel barriers can be made of the same material. In one embodiment, all cold metal layers are made of different cold metal materials and/or all tunnel barriers are made of different materials. In particular, different materials are used for the cold metal material layers and tunnel barrier layers.

FIG. 9c shows a multiple barrier planar NDR tunnel diode with triple barrier tunnel junctions. In this embodiment, the tunnel junction 264 has a first material layer 206 of a cold metal, an insulating material layer of a tunnel barrier 208, a second material layer 210 of a cold metal, another insulating material layer of a tunnel barrier 218, another material layer 220 of a cold metal, a further insulating material layer of a tunnel barrier 228, and a further material layer 230 of a cold metal. These layers are arranged in this exact order one after another aligned in one plane. All cold metal layers can be made of the same material and/or all tunnel barriers can be made of the same material. In one embodiment, all cold metal layers are made of different cold metal materials and/or all tunnel barriers are made of different materials. In particular, different materials are used for the cold metal material layers and tunnel barrier layers.

1.-15. (canceled)

16. Negative differential resistance tunnel diode comprising two terminals for connecting to an electrical circuit as well as a tunnel junction having a first material layer of a cold metal, an insulating material layer of a tunnel barrier, and a second material layer of a cold metal.

17. Negative differential resistance tunnel diode of claim 16, wherein the first material layer and the second material layer are of the same cold metal material.

18. Negative differential resistance tunnel diode of claim 16, wherein at least one dielectric layer is provided adjacent to the tunnel junction for depositing the first material layer, the insulating material layer of a tunnel barrier, and/or the second material layer.

19. Negative differential resistance tunnel diode of claim 16, wherein the cold metal can be identified by having in a density of states representation (DOS) of electrons of the cold metal: a conduction band width CBW starting at a Fermi Energy E_{F} level towards higher energy E, a valence band width VBW starting at the Fermi Energy E_{F} level towards lower energy E, a conduction band gap CBG adjacent to the conduction band width CBW towards higher energy E, and a valence band gap VBG adjacent to the valence band width VBW towards lower energy E.

20. Negative differential resistance tunnel diode of claim 16, wherein the cold metal is a material with spin-polarized ground state or a paramagnetic cold metal.

21. Negative differential resistance tunnel diode of claim 16, wherein the cold metal is TaX₂, wherein X is one of S, Se and Te.

22. Negative differential resistance tunnel diode of claim 16, wherein the tunnel junction is a planar tunnel junction, wherein the first material layer, the insulating material layer of the tunnel barrier and the second material layer are arranged on a same plane.

23. Negative differential resistance tunnel diode of claim 18, wherein the first material layer, the insulating material layer of the tunnel barrier (208) and the second material layer are deposited on a surface of the at least one dielectric layer, which is adjacent to the planar tunnel junction.

24. (New Negative differential resistance tunnel diode of claim 16, wherein the tunnel junction is a vertical tunnel junction, wherein the first material layer, the insulating material layer of the tunnel barrier and the second material layer are arranged in a stacked manner.

25. Negative differential resistance tunnel diode of claim 16, wherein the first material layer is protruding the insulating material layer of the tunnel barrier in a horizontal direction for connecting to the first terminal.

26. Negative differential resistance tunnel diode of claim 16, wherein the second material layer is protruding the insulating material layer of the tunnel barrier in an opposite horizontal direction for connecting to the second terminal.

27. Negative differential resistance tunnel diode of claim 16, wherein the first material layer and the insulating material layer of the tunnel barrier are twisted with an offset angle relatively to each other.

28. Negative differential resistance tunnel diode of claim 27, wherein the offset angle measures a rotation of a layer in the plane of the layer, i.e. about an axis that is oriented orthogonal to the layers.

29. Negative differential resistance tunnel diode of claim 16, wherein the insulating material layer of the tunnel barrier and the second material layer are twisted with an offset angle relatively to each other.

30. Negative differential resistance tunnel diode of claim 29, wherein the offset angle measures a rotation of a layer in the plane of the layer, i.e. about an axis that is oriented orthogonal to the layers.

31. Negative differential resistance tunnel diode of claim 16, wherein at least two of the first material layer, the insulating material layer of the tunnel barrier and the second material layer are twisted with an offset angle relatively to each other.

32. Negative differential resistance tunnel diode of claim 18, wherein the at least one dielectric layer fills a horizontal space between one of the terminals and the tunnel barrier.

33. Negative differential resistance tunnel diode of claim 16, wherein the tunnel junction is arranged between both terminals in a direction of long axes of the first and second material layer, which are extending in parallel to each other.

34. Use of the negative differential resistance tunnel diode of claim 16 for one of memory applications and logic applications.

35. Method for manufacturing a negative differential resistance tunnel diode, comprising the steps of:
Depositing a first material layer of a cold metal, an insulating material layer of a tunnel barrier and a second material layer of a cold metal;
Depositing a first terminal to the first material layer and the second terminal to the second material layer.
